(19) United States
(12) Patent Application Publication
(10) Pub. No.: US 2014/0120657 A1
(43) Pub. Date: May 1, 2014

(54) Back Channel Etching Oxide Thin Film Transistor Process Architecture

(71) Applicant: APPLE INC., Cupertino, CA (US)

(72) Inventors: Ming-Chin Hung, Cupertino, CA (US); Kyung Wook Kim, Cupertino, CA (US); Chun-Yao Huang, Cupertino, CA (US); Young Bae Park, Cupertino, CA (US); Shih Chang Chang, Cupertino, CA (US); John Z. Zhong, Cupertino, CA (US)

(73) Assignee: Apple Inc., Cupertino, CA (US)

(21) Appl. No.: 13/664,240

(22) Filed: Oct. 30, 2012

(51) Int. Cl. H01L 21/36

(52) U.S. Cl. 438/104; 257/E21.461

(57) ABSTRACT

A method is provided for fabricating a back channel etching (BCE) oxide thin film transistor (TFT) for a liquid crystal display. The method includes forming a first metal layer having a first portion and a second portion over a substrate, depositing a gate insulator over the first metal layer, and disposing a semiconductor layer over the gate insulator. The method also includes depositing a half-tone photoresist to cover a first portion of the semiconductor layer and the first portion of the first metal layer. The half-tone photoresist has a first portion and a second portion thicker than the first portion. The first portion has a via hole above the second portion of the first metal layer. The second portion of the half-tone photoresist covers the first portion of the first metal layer. The method further includes etching a portion of the gate insulator through the via hole such that the second portion of the first metal layer is exposed, removing the first portion of the half-tone photoresist while remaining the second portion of the half-tone photoresist, and etching to remove a second portion of the semiconductor layer that is not covered by the half-tone photoresist.

### TECHNICAL FIELD

Embodiments described herein generally relate to process architecture for oxide thin film transistor (TFT) in an active matrix liquid crystal display (AMLCD). More specifically, certain embodiments relate to processes for back channel etching (BCE) oxide TFTs.

### BACKGROUND

Liquid crystal displays (LCDs) generally display images by transmitting or blocking light through the action of liquid crystals. LCDs have been used in a variety of computing displays and devices, including notebook computers, desktop computers, tablet computing devices, mobile phones (including smart phones) automobile in-cabin displays, on appliances, as televisions, and so on. LCDs often use an active matrix to drive liquid crystals in a pixel region. In some LCDs, a thin-film transistor (TFT) is used as a switching element in the active matrix.

Back channel etching (BCE) of oxide TFTs has become increasingly important in the recent development of active matrix liquid crystal displays (AMLCDs), because of such displays' small sizes and the small parasitic capacitance that may be achieved through BCE, as compared to a conventional via-hole oxide TFT.

A BCE oxide TFT generally includes a passivation layer over a gate insulator and may require etching through both the passivation layer and the gate insulator to form a via hole. The passivation layer commonly is formed from silicon oxide (SiO₂), while the gate insulator commonly is formed from silicon nitride (SiNx), which etches much faster than SiO₂ when certain etchants are employed. Generally, the very different etching rates between the passivation layer and the gate insulator may produce an undercut in the via hole, which may lead to a break in the conductive material used to coat the via, thereby interfering with operation of the TFTs.

A conventional fabrication approach for a BCE oxide TFT uses dedicated masks for etching SiO₂ and SiNx separately , which may increase production time and decrease product throughput. Further, each mask that is used adds a chance that the TFT being produced will be inoperable. Thus, it may be desirable to employ a more efficient manufacturing process, such as one that has a reduced number of mask operations.

### SUMMARY

Embodiments described herein may provide process architecture for the oxide TFT in active matrix liquid crystal display (AMLCD). The oxide TFT may use a semiconductor, such as indium-gallium-zinc-oxide (IGZO) among others. The disclosed process architecture reduces the number of masks required for processing and provides oxide TFTs without the undercut issue as discussed above.

In one embodiment, a method is provided for fabricating a back channel etching (BCE) oxide thin film transistor (TFT) for a liquid crystal display. The method includes forming a first metal layer having a first portion and a second portion over a substrate, depositing a gate insulator over the first metal layer, and disposing a semiconductor layer over the gate insulator. The method also includes depositing a half-tone photoresist to cover a first portion of the semiconductor layer and the first portion of the first metal layer. The half-tone photoresist has a first portion and a second portion thicker than the first portion. The first portion has a via hole above the second portion of the first metal layer. The second portion of the half-tone photoresist covers the first portion of the first metal layer. The method further includes etching a portion of the gate insulator through the via hole such that the second portion of the first metal layer is exposed, removing the first portion of the half-tone photoresist while remaining the second portion of the half-tone photoresist, and etching to remove a second portion of the semiconductor layer that is not covered by the half-tone photoresist.

In another embodiment, a method is provided for fabricating a back channel etching (BCE) oxide thin film transistor (TFT) for a liquid crystal display. The method includes forming a first metal layer having a first portion and a second portion over a substrate, depositing a gate insulator over the first metal layer, and disposing a semiconductor layer over the gate insulator. The method also includes depositing a second metal layer to form a source electrode and a drain electrode over the semiconductor layer, the source electrode and drain electrode being above the first portion of the first metal layer. The method further includes disposing a first passivation layer over the source electrode and drain electrode, the first passivation layer having a first portion over the source electrode and the drain electrode and a second portion beyond the source electrode and the drain electrode. The method also includes covering the first portion of the first passivation layer by a photoresist layer and etching to remove the second portion of the first passivation layer. The method further includes etching to remove a first portion of the semiconductor layer such that a remaining second portion of the semiconductor layer has substantially the same dimension as the first portion of the first passivation layer.

In yet another embodiment, a method is provided for fabricating a back channel etching (BCE) oxide thin film transistor (TFT) for a liquid crystal display. The method includes forming a first metal layer having a first portion and a second portion over a substrate, depositing a gate insulator over the first metal layer, and forming a patterned semiconductor layer over the gate insulator above the first portion of the first metal layer. The method also includes depositing a second metal layer to form a source electrode and a drain electrode over the patterned semiconductor layer. The method further includes depositing an organic passivation layer over the source electrode and the drain electrode.

In still yet another embodiment, a method is provide for fabricating a back channel etching (BCE) oxide thin film transistor (TFT) for a liquid crystal display. The method includes forming a first metal layer having a first portion and a second portion over a substrate, and forming a plurality of layers over the first metal layer. The plurality of layers includes a gate insulator over the first metal layer, a semiconductor layer over the gate insulator, a second metal layer over the semiconductor layer, and a first passivation layer over the second metal layer. Each of the semiconductor layer, the second metal layer, and the first passivation layer includes a first portion above the first portion of the first metal layer. The method also includes forming a half-tone photoresist over the first portion of the first passivation layer, the half-tone photoresist having a first middle portion being thinner than a second remaining portion. The method further includes etching to remove a second portion of the first passivation layer, a second portion of the second metal layer, and a second portion of the semiconductor layer, the second portions being not covered by the half-tone photoresist. The method also includes removing the first middle portion of the half-tone photoresist, and etching to remove a portion of the first passivation layer and a portion of the second metal layer to form a source electrode and a drain electrode separated by a back channel above the semiconductor layer.

Additional embodiments and features are set forth in part in the description that follows, and in part will become apparent to those skilled in the art upon examination of the specification or may be learned by the practice of the embodiments discussed herein. A further understanding of the nature and advantages of certain embodiments may be realized by reference to the remaining portions of the specification and the drawings, which forms a part of this disclosure.

### BRIEF DESCRIPTION OF THE DRAWINGS

FIG. 1 illustrates a perspective view of a sample electronic device.

FIG. 2A shows a cross-sectional view of an oxide TFT for an AMLCD in according to embodiments of the present disclosure. FIG. 2B shows an enlarged view of circled area of FIG. 2A (see dashed line area).

FIG. 3A shows a cross-sectional view of a process architecture including gate photo patterning and indium-gallium-zinc-oxide (IGZO) photo patterning for the oxide TFT of the AMLCD.

FIG. 3B shows a cross-sectional view of the process architecture including via hole photo patterning for the oxide TFT of the AMLCD following the operation of FIG. 3A.

FIG. 3C shows a cross-sectional view of the process architecture including source/drain photo patterning for the oxide TFT of the AMLCD following the operation of FIG. 3B.

FIG. 3D shows a cross-sectional view of the process architecture including organic passivation photo patterning and common electrode photo patterning for the oxide TFT of the AMLCD following the operation of FIG. 3C.

FIG. 3E shows a cross-sectional view of the process including second passivation/first passivation photo patterning and pixel electrode photo patterning for the oxide TFT of the AMLCD following the operation of FIG. 3D.

FIG. 4A shows a cross-sectional view of a process architecture including gate photo patterning for the oxide TFT of the AMLCD in a first embodiment.

FIG. 4B shows a cross-sectional view of the process architecture including halftone IGZO/via hole photo patterning for the oxide TFT of the AMLCD following the operation of FIG. 4A.

FIG. 4C shows a cross-sectional view of the process architecture including source/drain photo patterning for the oxide TFT of the AMLCD following the operation of FIG. 4B.

FIG. 4D shows a cross-sectional view of the process architecture including organic passivation photo patterning and common electrode photo patterning for the oxide TFT of the AMLCD following the operation of FIG. 4C.

FIG. 4E shows a cross-sectional view of the process architecture including second passivation/first passivation photo patterning and pixel electrode photo patterning for the oxide TFT of the AMLCD following the operation of FIG. 4D.

FIG. 5A shows a cross-sectional view of a process architecture including gate photo patterning for the oxide TFT of the AMLCD in a second embodiment.

FIG. 5B shows a cross-sectional view of the process architecture including source/drain photo patterning for the oxide TFT of the AMLCD following the operation of FIG. 5A.

FIG. 5C shows a cross-sectional view of the process architecture including first passivation/IGZO photo patterning for the oxide TFT of the AMLCD following the operation of FIG. 5B.

FIG. 5D shows a cross-sectional view of the process architecture including organic passivation photo patterning and common electrode photo patterning for the oxide TFT of the AMLCD following the operation of FIG. 5C.

FIG. 5E shows a cross-sectional view of the process architecture including second passivation photo patterning and pixel electrode photo patterning for the oxide TFT of the AMLCD following the operation of FIG. 5D.

FIG. 6A shows a cross-sectional view of the process architecture including gate photo patterning and IGZO photo patterning for the oxide TFT of the AMLCD in a third embodiment.

FIG. 6B shows a cross-sectional view of source/drain photo patterning for the oxide TFT of the AMLCD following the operation of FIG. 6A.

FIG. 6C shows a cross-sectional view of the process architecture including organic passivation photo patterning and common electrode photo patterning for the oxide TFT of the AMLCD following the operation of FIG. 6B.

FIG. 6D shows a cross-sectional view of the process architecture including second passivation photo patterning and pixel electrode photo patterning for the oxide TFT of the AMLCD following the operation of FIG. 6C.

FIG. 7A shows a cross-sectional view of the process architecture including gate photo patterning for the oxide TFT of the AMLCD in a fourth embodiment.

FIG. 7B shows a cross-sectional view of the process architecture including half-tone first passivation/source/drain/IGZO photo patterning for the oxide TFT of the AMLCD following the operation of FIG. 7A.

FIG. 7C shows a cross-sectional view of the process architecture including back channel forming for the oxide TFT of the AMLCD following the operation of FIG. 7B.

FIG. 7D shows a cross-sectional view of organic passivation photo patterning and common electrode photo patterning for the oxide TFT of the AMLCD following the operation of FIG. 7C.

FIG. 7E shows a cross-sectional view of the process architecture including second passivation photo patterning and pixel electrode photo patterning for the oxide TFT of the AMLCD following the operation of FIG. 7D.

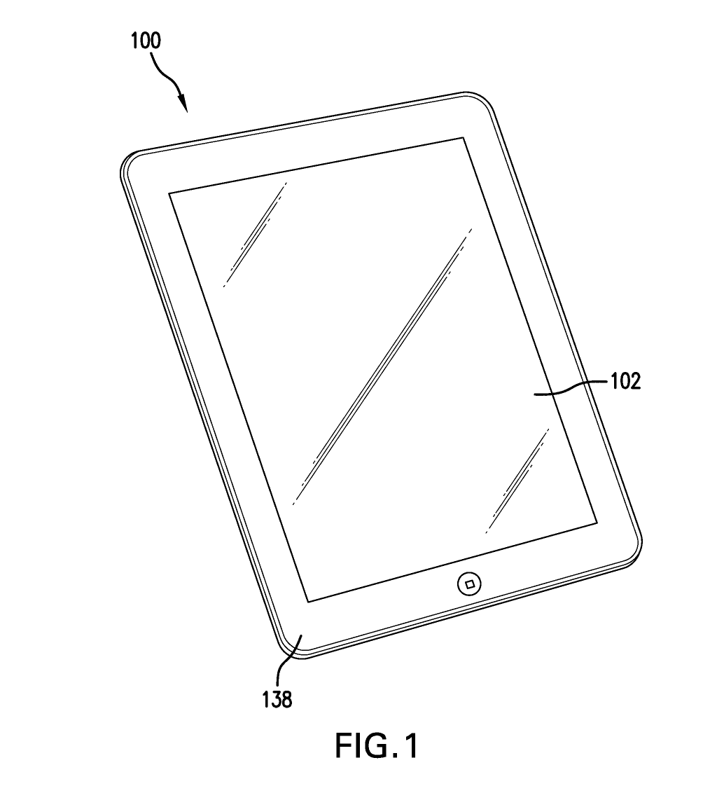

### DETAILED DESCRIPTION

The present disclosure may be understood by reference to the following detailed description, taken in conjunction with the drawings as described below. It is noted that, for purposes of illustrative clarity, certain elements in various drawings may not be drawn to scale.

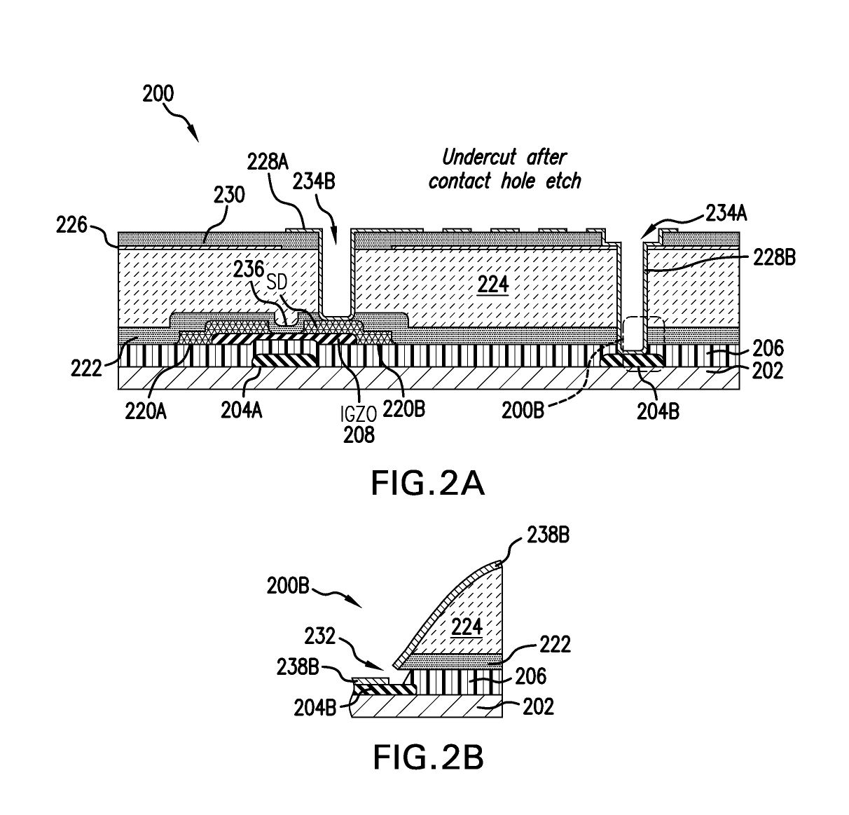

FIG. 2A shows a cross-sectional view of an oxide TFT for an AMLCD in according to embodiments of the present disclosure. The oxide TFT 200 includes a substrate 202, a first metal layer including a gate electrode 204A and a metal common electrode 204B disposed over the substrate 202. The oxide TFT 200 also includes a gate insulator 206 disposed over the gate electrode 204A and the metal common electrode 204B. The oxide TFT 200 also includes a semiconductor, such as an IGZO layer 208 disposed over the gate insulator 206 above the gate electrode 204. The oxide TFT 200 further has a second metal layer including a source electrode 220A and drain electrode 220B disposed over the IGZO 208. The source electrode and drain electrode are separated by a back channel 236 above IGZO. It will be appreciated by those skilled in the art that the source and drain electrodes may be interchangeable.

The oxide TFT 200 further includes a first passivation layer 222 over the source/drain electrodes. The first passivation layer 222 covers the back channel 236 above the IGZO. The oxide TFT 200 further includes an organic passivation layer 224 disposed over the first passivation layer 222, a first conductive layer, such as indium-tin-oxide (ITO) or an ITO common electrode 226 disposed over the organic passivation layer 224, and a second passivation layer disposed over the ITO common electrode 226 and the organic passivation layer 224. The organic passivation layer provides a flat surface for forming more layers, such as a common electrode and a pixel electrode, among others.

The first passivation layer 222 helps prevent the IGZO 208 from absorbing moisture from the organic passivation layer or PAC. The first passivation layer 222 may use SiO₂ rather than SiNx to reduce the hydrogen penetration from SiNx deposition process. Generally, IGZO is also sensitive to moisture while the organic passivation layer, such as photoactive compound (PAC), absorbs moisture. The first passivation layer 222 covers the back channel above the IGZO and thus protects the IGZO from moisture absorption.

The first passivation layer 222 also helps prevent the copper diffusion into the PAC 224 and helps reduce corrosion of the copper or source/drain electrodes. The first passivation layer 222 separates the source/drain electrodes 220A-B from the PAC 224.

The source/drain electrodes may be formed of a metal, such a copper. Copper has better conductivity than aluminum, but diffuses more than aluminum. Furthermore, the first passivation layer 222 also provides better adhesion to the PAC 224 than the source/drain electrodes 220A-B to the PAC 224.

The oxide TFT 200 further includes a second conductive layer or ITO layer that includes a pixel electrode 228A disposed over the second passivation layer 230 and also a bridge that connects the ITO common electrode 226 to the metal common electrode 204B through a first via hole 234A. The pixel electrode 228A is connected to the drain electrode 220B through a second via hole 234B. Both the first and second via holes are through the first and second passivation layers and the organic passivation layer 224.

The first passivation layer 222 is often formed of silicon oxide (SiO₂), while the gate insulator 206 may be formed of silicon nitride (SiNx) or SiO₂.

The IGZO 208 may be replaced by other semiconductors. It will be appreciated by those skilled in the art that the semiconductor layer may include other materials, for example, zinc oxide (ZnO), indium oxide (InO), gallium oxide (GaO), tin oxide (SnO2), indium gallium oxide (IGO), indium zinc oxide (IZO), zinc tin oxide (ZTO), or indium zinc tin oxide (IZTO) among others.

The organic passivation layer 224 may be formed of an organic material, such as a photoactive compound (PAC), an acrylate, or an organic-inorganic hybrid like siloxane to provide a flat surface for forming more layers, including the common electrode and the pixel electrode. Furthermore, the photoactive compound (PAC) could be positive tone or negative tone material. The polymer bases may be acrylate, cyclic olefin polymer, or siloxane among others. The PAC has a relatively low dielectric constant, considerably lower than the first and second passivation layers and.

The first conductive layer or common electrode 226 and the second conductive layer (pixel electrode 228A and bridge 228B) may be formed of a transparent conductor, such as indium-tin oxide (ITO), indium zinc oxide (IZO) among others.

The gate insulator 206 may be formed of an inorganic insulation film including silicon oxide (SiO₂), silicon nitride (SiNx), a dielectric oxide film such as aluminum oxide (Al₂O₃), or an organic material, and the like.

The gate insulator 206 may also include multiple layers of the above materials. In a particular embodiment, the gate insulator may have a two-layer structure. A silicon nitride layer may be formed as a first insulating layer and a silicon oxide layer may be formed as a second insulating layer.

To fabricate such an oxide TFT 200, if the first passivation layer and the gate insulator are etched together, an undercut 232 may be formed near the bottom of the first via hole 234A due to different etching rates of the SiO₂ and SiNx as shown in FIG. 2B. An enlarged view of the undercut area in the dashed line is shown above the first via hole 234A in FIG. 2B. The undercut for the SiNx 206 under the first passivation layer 222 may cause poor connection between the bridge 228B and the metal common electrode 204B.

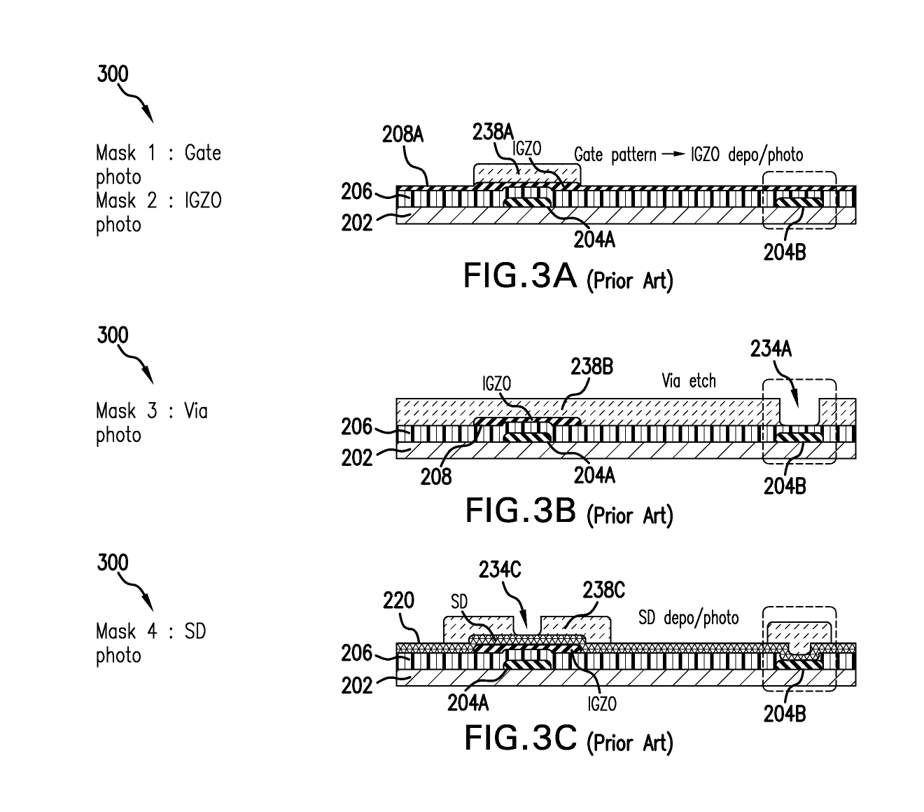

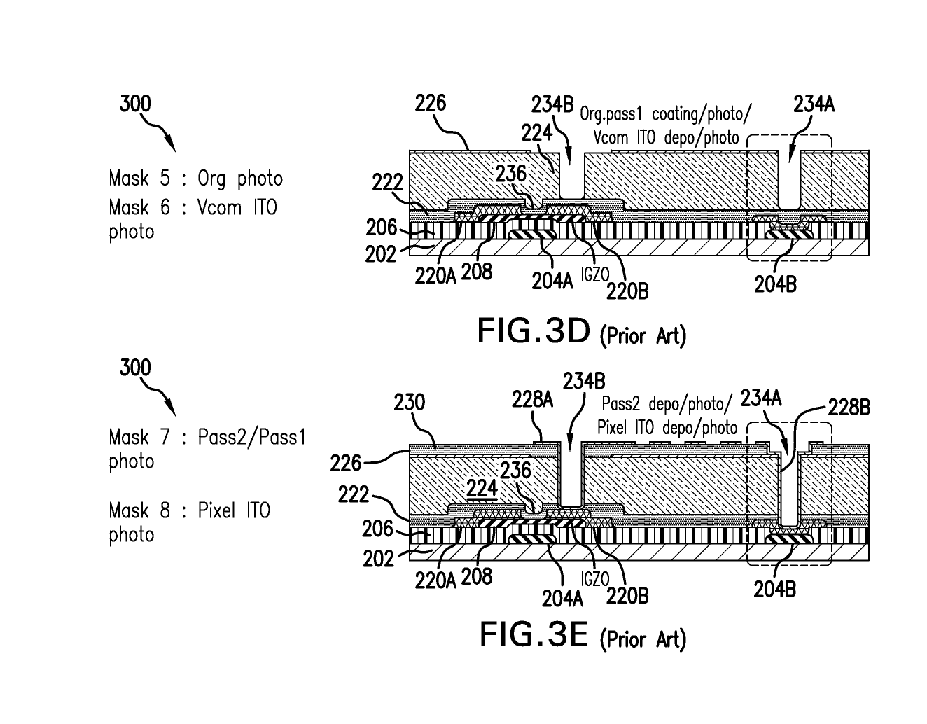

FIGS. 3A-3E illustrate cross-sectional view of the oxide TFT at various operations of photo patterning in a conventional process which resolves the undercut issue. However, this process may require an additional mask for the photo patterning, i.e. a total of eight masks in photo patterning.

For photo patterning or lithography, a photoresist is first deposited on a surface, and then light is selectively passed through a patterned mask that may block light in certain areas. The exposed photoresist film is developed through the patterned mask to form the photoresist patterns as shown. The exposed photoresist film protects the layers underneath during an etching process, such that the portion exposed by the photoresist may be completely removed by the etching process, such as a wet etching. Portions of underlying layers that are protected by photoresist generally are not removed or otherwise etched. After etching to form a pattern of a deposited layer by using photoresist, the insoluble photoresist is removed prior to the next deposition operation. Different masks may be provided to form various films with different patterns. In alternative embodiments, different photoresist may be used.

The photoresist film may be made of a photosensitive material; exposure to light (or particular wavelengths of light) may develop the photoresist. The developed photoresist may be insoluble or soluble to a developer. There may be two types of photoresist, a positive photoresist and a negative photoresist. The positive photoresist is soluble to the photoresist developer. The portion of the positive photoresist that is unexposed remains insoluble to the photoresist developer. The negative resist is a type of photoresist in which the portion of the photoresist that is exposed to light becomes insoluble to the photoresist developer. The unexposed portion of the photoresist is dissolved by the photoresist developer.

FIG. 3A shows a cross-sectional view of a conventional process including gate photo patterning and indium-gallium-zinc-oxide (IGZO) photo patterning for the oxide TFT of the AMLCD. A first photo mask is used to form the gate electrode 204A and a metal common electrode 204B after depositing a first metal layer during the gate photo patterning. A second photo mask is used to form a first photoresist 238A disposed over the IGZO 208A during the IGZO photo patterning. By using the first photoresist 238A to protect the IGZO underneath and etching away the exposed portion of the IGZO 208A, the IGZO 208 is formed.

FIG. 3B shows a cross-sectional view of the conventional process including via hole photo patterning for the oxide TFT of the conventional AMLCD following the operation of FIG. 3A. A second photoresist 238B covers the IGZO and the gate insulator 206, but exposes a portion above the gate electrode 204A to form a via hole 234A during the via hole photo patterning. The via hole 234A allows an exposed portion of the gate insulator 206 above the metal common electrode 204B to be etched away.

FIG. 3C shows a cross-sectional view of the conventional process including source/drain photo patterning for the oxide TFT of the conventional AMLCD following the operation of FIG. 3B. A second metal layer 220 is disposed over the IGZO to form the source/drain electrodes. A fourth mask is used to form a third photoresist 238C, which is formed above the source/drain electrode layer 220 and has a via hole 234C above the gate electrode 204. This via hole 234C allows the exposed portion of the source/drain layer 220 to be removed to form a back channel above the IGZO. The photoresist 238C also covers a portion of the second metal layer 220 above the metal common electrode 204B. This allows to remain a portion of the second metal layer above the metal common electrode 204B.

FIG. 3D shows a cross-sectional view of the conventional process including organic passivation photo patterning and common electrode photo patterning for the oxide TFT of the conventional AMLCD following the operation of FIG. 3C. A fifth mask is used to form via holes 234B and 234A above the drain electrode 220B and the metal common electrode 204B, respectively. A sixth mask is used to form the ITO common electrode 226 on top of the organic passivation layer 224.

FIG. 3E shows a cross-sectional view of the conventional process including second passivation/first passivation photo patterning and pixel electrode photo patterning for the oxide TFT of the conventional AMLCD following the operation of FIG. 3D. A seventh mask is used to form via holes 234B and 234A through the second passivation layer 230 and the first passivation layer 222. An eighth mask is used to form the pixel electrode 228A and a bridge 228B connecting the metal common electrode 204B to the ITO common electrode 226 from a second conductive layer or ITO layer. This combined common electrode that includes the metal common electrode 204B and the ITO common electrode 226 has a lower resistivity than the ITO common electrode 226 due to lower resistivity of the metal than the ITO, which helps reduce common electrode resistance.

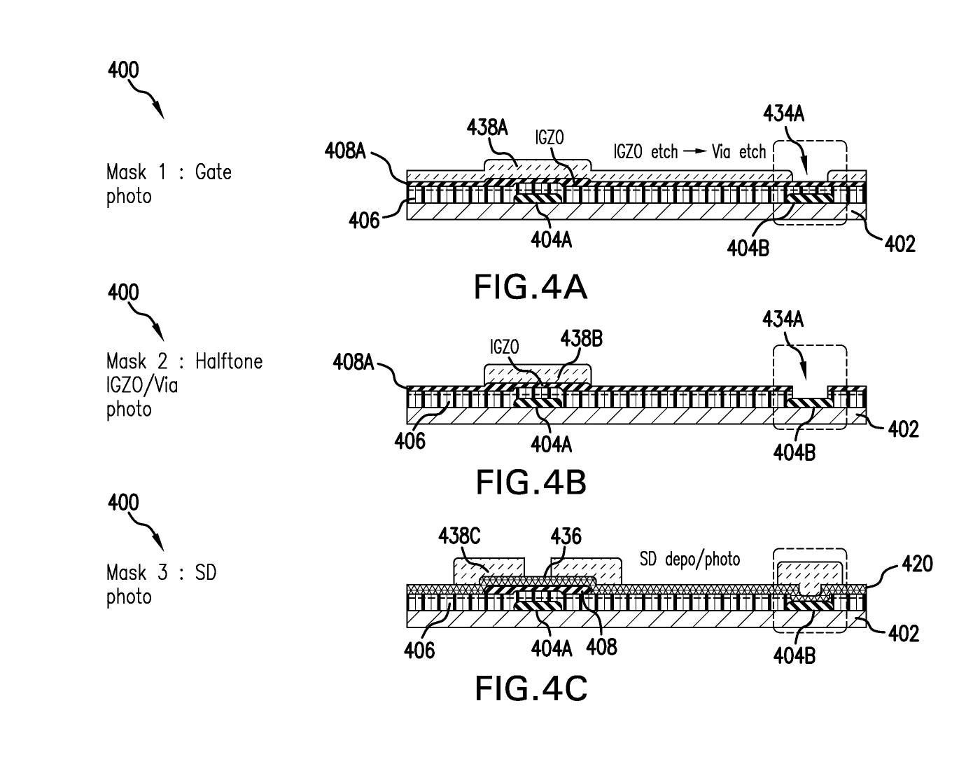

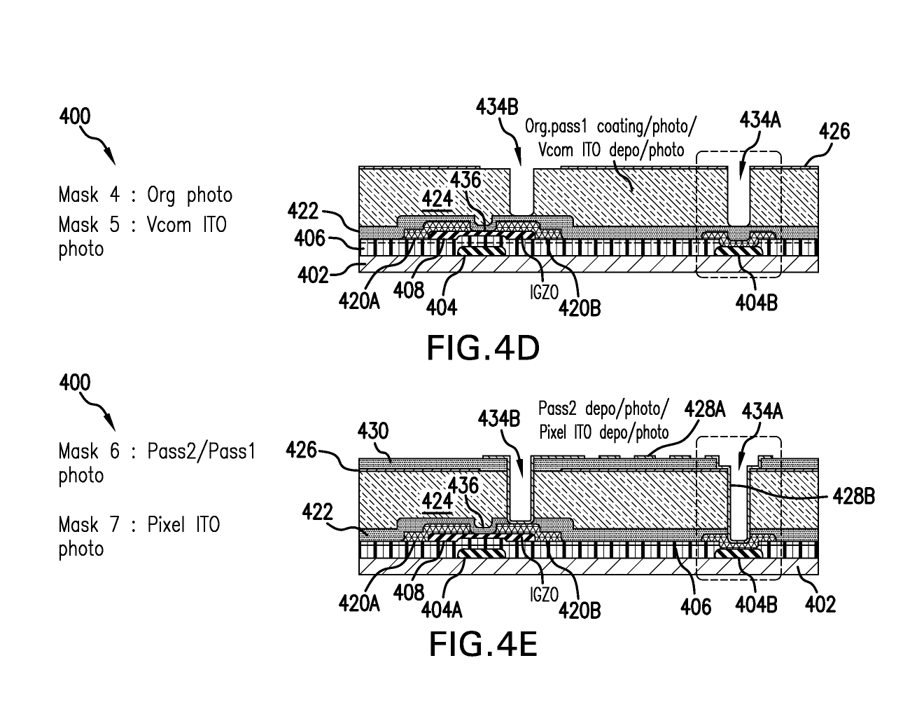

To reduce the number of masks, several embodiments of the process architecture are provided below. FIGS. 4A-4E illustrate a process architecture 400 which uses a total of seven masks for fabrication of the oxide TFT. FIG. 4A shows a cross-sectional view of the process architecture 400 including gate photo patterning for the oxide TFT of the AMLCD in a first embodiment. A first mask is used to patterning a gate electrode 404A and a metal common electrode 404B from a first metal layer, which is disposed over a substrate 402. A first half-tone photoresist 438A is formed with a second mask. The half-tone photoresist 438A includes a thicker portion above the gate electrode 404, but has a via hole 434A above the metal common electrode 404B.

FIG. 4B shows a cross-sectional view of the process architecture including half-tone IGZO/via hole photo patterning for the oxide TFT of the AMLCD following the operation of FIG. 4A. The via hole 434A allows an exposed portion of a semiconductor layer 408A, e.g. Semiconductor layer 408A, and an exposed portion of the gate insulator 406 to be etched away. The remaining thicker portion 438B of the photoresist 438A is above the gate electrode 402, which allows to remove the exposed portion of the semiconductor layer 408A to form patterned semiconductor layer 408.

FIG. 4C shows a cross-sectional view of the process architecture including source/drain photo patterning for the oxide TFT of the AMLCD following the operation of FIG. 4B. A source/drain layer 420 is disposed over the patterned semiconductor layer 408. A third photo mask is used to form a second photoresist 438C having a via hole 436A during source/drain photo patterning. The second photoresist 438C covers a portion of the source/drain layer 420. The exposed portion of the source/drain layer 420 may be removed by etching to form the source/drain electrodes 420A-B. Between the source/drain electrodes is a back channel 436.

FIG. 4D shows a cross-sectional view of the process architecture including organic passivation photo patterning and common electrode photo patterning for the oxide TFT of the AMLCD following the operation of FIG. 4C. A first passivation layer 422 is deposited over the source/drain electrode 420A-B and the gate insulator 406, as well as the semiconductor layer 408 in the back channel 436. An organic passivation layer is deposited over the first passivation layer 422. A fourth mask is used to form first and second via holes 434A-B through the organic passivation layer. A conductive layer, such as ITO layer, is deposited over the organic passivation layer. Patterned ITO common electrode 426 is formed with a fifth mask.

FIG. 4E shows a cross-sectional view of the process architecture including second passivation/first passivation photo patterning and pixel electrode photo patterning for the oxide TFT of the AMLCD following the operation of FIG. 4D. A second passivation layer 430 is deposited over the ITO common electrode 426 and the organic passivation layer 424. The second passivation layer and the first passivation layer have first and second via holes 434A-B above the metal common electrode 404B and the drain electrode 420B, respectively. The via holes through the first and second passivation layers are formed by using a sixth mask. A second conductive layer, such as indium-tin-oxide (ITO), is deposited over the metal common electrode 404B through via hole 434A and the second passivation layer 430. Pixel electrode 428A is formed by using a seventh mask to remove exposed portion of the second conductive layer. Additionally, a conductive bridge 428B is also formed from the second conductive layer inside the dashed-line in a rectangular shape. The conductive bridge 428B is not connected to the pixel electrode 428A.

The finished oxide TFT as shown in FIG. 4E is the same as that shown in FIG. 3E, but a total of seven masks are needed for the process architecture 400. The gate insulator 406 may include one layer of SiNx or SiO₂.

Optionally, the gate insulator 406 may include two layers, a bottom SiNx layer and a top SiO₂ layer as shown by dashed-line. The SiO₂ contacts the semiconductor layer 408, which is very sensitive to hydrogen. The reason for use of the top SiO₂ layer is because SiO₂ contains less hydrogen than SiNx. The reason for using the bottom SiNx to cover the gate electrode is that SiNx has a higher dielectric constant than SiO₂ and thus is a better barrier to copper than SiO₂. This gate insulator may prevent an impurity such as moisture or alkali metal or copper contamination from diffusing into a TFT element and a display device and may also improve reliability of a semiconductor element formed in an element formation layer, or the like.

The oxide TFT formed from process architecture 400 includes the first passivation layer 422 between the semiconductor layer 408 and the organic passivation 424 or PAC in the back channel 436.

The second passivation layer 430 may use SiNx, because SiNx has a higher dielectric constant than SiO₂, and matches to a storage capacitor better than SiO₂. The storage capacitor is to hold the charge or voltage during frame change.

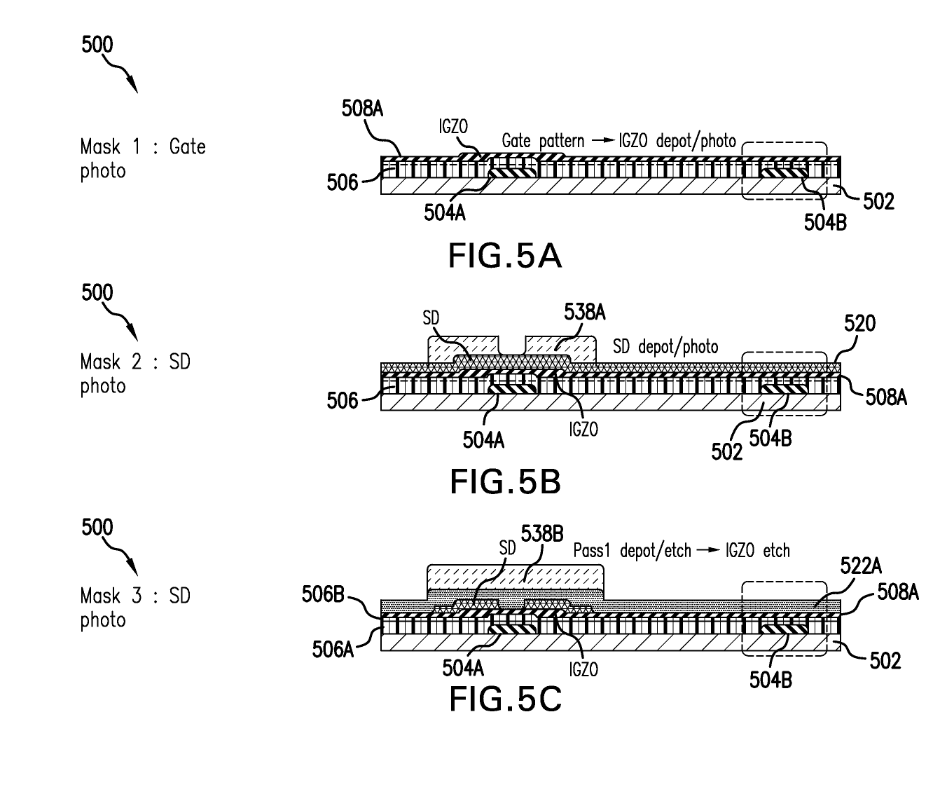

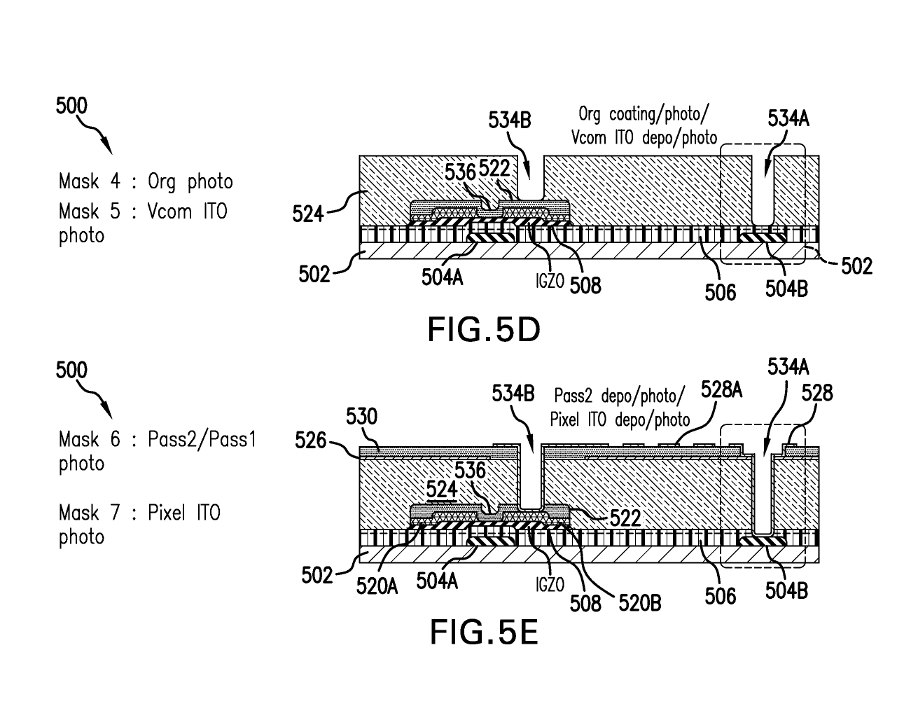

FIGS. 5A-E illustrate a process architecture 500 which also uses a total of seven masks. FIG. 5A shows a cross-sectional view of a process architecture including gate photo patterning for the oxide TFT of the AMLCD in a second embodiment. Similar to process architecture 400, a first mask is used to form gate electrode 504A and metal common electrode 504B over a substrate 502 from a first metal layer. A gate insulator layer 506 is deposited to cover the gate electrode 504 and the substrate 502. An IGZO layer 508A is formed on top of the gate insulator 506.

FIG. 5B shows a cross-sectional view of the process architecture including source/drain photo patterning for the oxide TFT of the AMLCD following the operation of FIG. 5A. A second metal layer 520 is formed on top of the IGZO layer 508A. Then, a first photoresist 538A is formed by using a second mask to cover a portion of the second metal layer 520. Source/drain electrodes 520A-B are formed from the second metal layer 520 by using the first photoresist 538A. Between the source/drain electrodes 520A-B is a back channel 536 where the IGZO is exposed.

FIG. 5C shows a cross-sectional view of the process architecture including first passivation/IGZO photo patterning for the oxide TFT of the AMLCD following the operation of FIG. 5B. A first passivation layer 522 is formed over the source/drain electrodes 520A-B. a second photoresist 538B formed by using a third mask covers a portion of the first passivation layer 522 above the source/drain electrodes. The second photoresist 538B allows the exposed portion of the first passivation layer 522A and IGZO layer 508A to be removed by etching to form IGZO 508 and the first passivation 522.

FIG. 5D shows a cross-sectional view of the process architecture including organic passivation photo patterning and common electrode photo patterning for the oxide TFT of the AMLCD following the operation of FIG. 5C. An organic passivation layer 524 is formed over the first passivation 522 and the exposed portion of the gate insulator 506. Via holes 534A-B in the organic passivation layer 524 are formed by using a fourth mask. The IGZO 508 and the first passivation 522 have about the same width as the source/drain electrodes, such that the two opposite ends of the source/drain electrodes 520A-B are exposed to the organic passivation layer 524.

FIG. 5E shows a cross-sectional view of the process architecture including second passivation photo patterning and pixel electrode photo patterning for the oxide TFT of the AMLCD following the operation of FIG. 5D. ITO common electrode 526 is formed from a first conductive layer or ITO layer by using a fifth mask over the organic passivation layer 524. A second passivation layer 530 is formed over the ITO common electrode 526 and the organic passivation layer 524. Via holes 534A-B are formed in the second passivation layer 530 by using a sixth mask. A second conductive layer or ITO layer is formed over the second passivation layer 530, followed by a photo patterning using a seventh mask to form ITO pixel electrode 528A and bridge 528B that connects the metal common electrode 504B to the ITO common electrode 526. As shown in FIG. 5E, the IGZO dimension is defined by the first passivation layer 522 and the source/drain electrodes pattern.

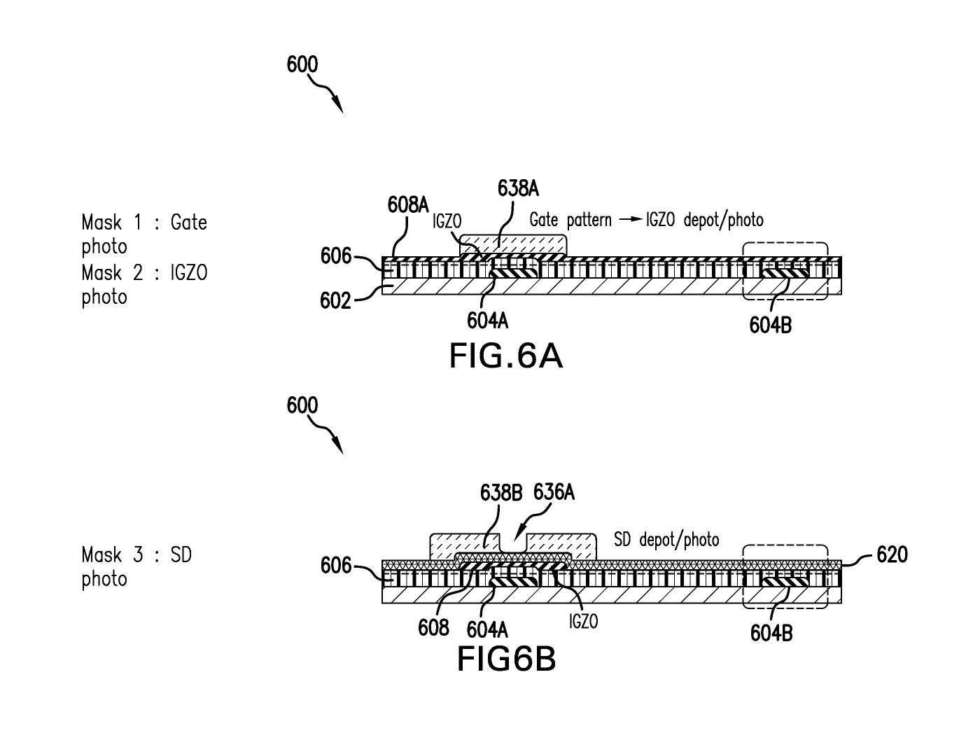

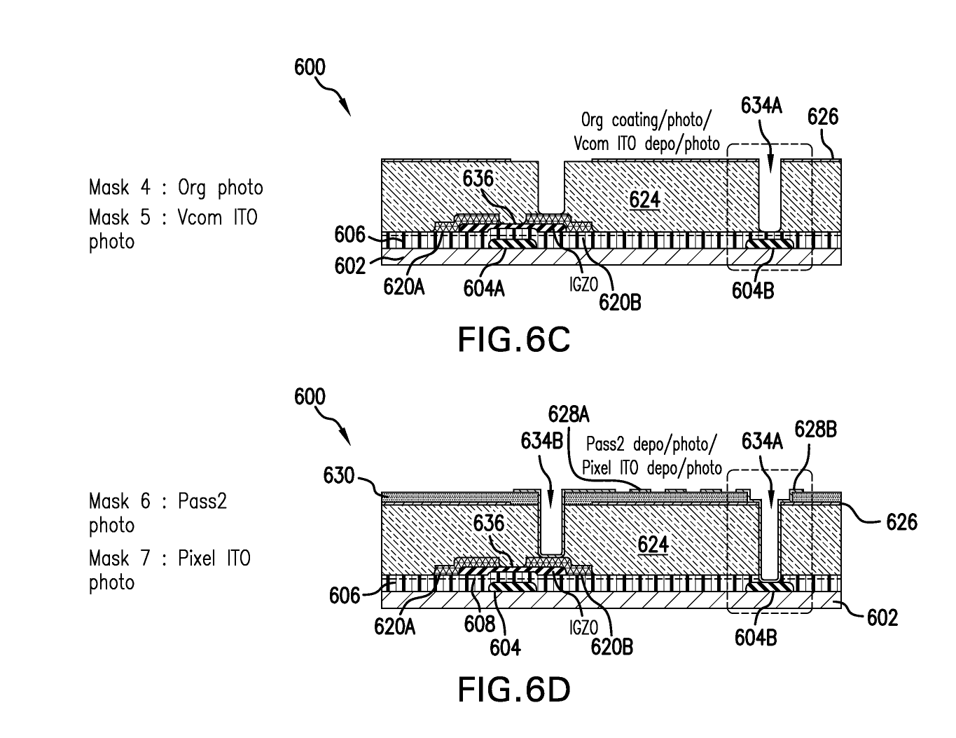

FIGS. 6A-6E illustrate a process architecture 600 which uses a total of seven masks for fabrication of the oxide TFT. This process architecture 600 removes the first passivation layer as shown in architecture 400. FIG. 6A shows a cross-sectional view of the process architecture including gate photo patterning and IGZO photo patterning for the oxide TFT of the AMLCD in a third embodiment. Gate electrode 604A and metal common electrode 604B are formed from a first metal layer over a substrate 602 by using a first photo mask. IGZO 608 is formed by a photoresist 638A formed with a second mask over the gate insulator 606 that covers the gate electrode 604.

FIG. 6B shows a cross-sectional view of source/drain photo patterning for the oxide TFT of the AMLCD following the operation of FIG. 6A. A metal conductive layer is deposited over the IGZO 608 and the gate insulator 606. A second photoresist 638B has a via hole 636A formed by a third mask. Source/drain electrodes 620A-B shown in FIG. 6C are formed by the second photoresist 638B.

FIG. 6C shows a cross-sectional view of the process architecture including organic passivation photo patterning and common electrode photo patterning for the oxide TFT of the AMLCD following the operation of FIG. 6B. An organic passivation layer 624 is formed over the source/drain electrodes 620A-B and the gate insulator 606. Via holes 634A-B are formed in the organic passivation layer 624 by using a fourth mask. Common electrode 626 is formed from a first conductive layer or ITO layer by using a fifth mask.

FIG. 6D shows a cross-sectional view of the process architecture including second passivation photo patterning and pixel electrode photo patterning for the oxide TFT of the AMLCD following the operation of FIG. 6C. A second passivation layer 630 is deposited over the ITO common electrode 626 and the organic passivation layer 624. Via holes 634A-B in the second passivation layer 630 are formed by a sixth mask. Finally, pixel electrode 628A is formed from a second ITO layer by a seventh mask. Also, a bridge 628B through via hole 634A is formed from the second ITO layer to connect the ITO common electrode 626 to the metal common electrode 604B.

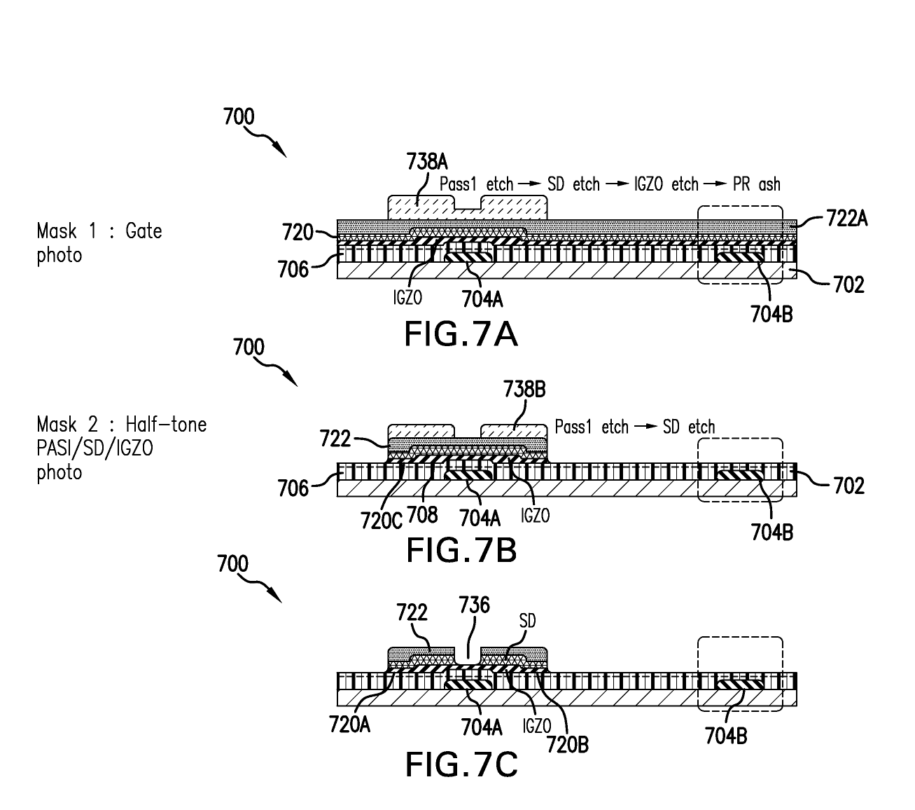

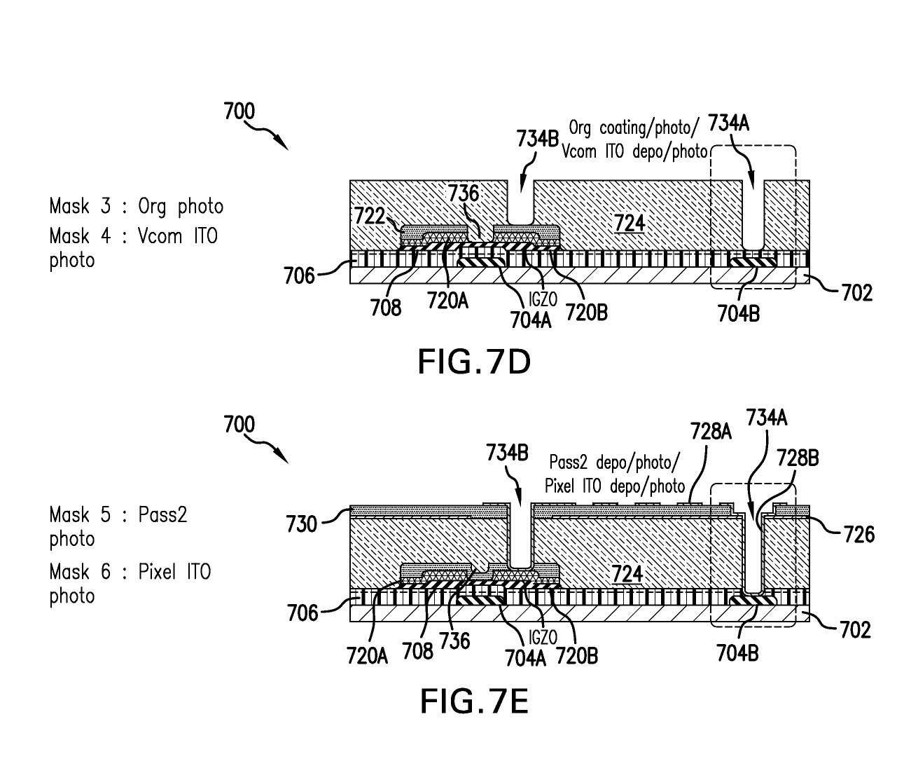

FIGS. 7A-7E illustrate process architecture that uses a total of six masks. FIG. 7A shows a cross-sectional view of the process architecture including gate photo patterning for the oxide TFT of the AMLCD in a fourth embodiment. Gate electrode 704A and metal common electrode 704B are formed from a first metal layer over a substrate 702 by using a first photo mask. A half-tone photoresist 738A is on top of the first passivation layer 722A. The half-tone photoresist has a thinner portion in the middle above the gate electrode 704.

FIG. 7B shows a cross-sectional view of the process architecture including half-tone first passivation/source/drain/IGZO photo patterning for the oxide TFT of the AMLCD following the operation of FIG. 7A. The half-tone photoresist 738A is formed with a second mask. By using the half-tone photoresist, the first passivation layer 722 is first formed by etching the exposed portion of the first passivation layer, and then a source/drain layer 720C is formed by etching the exposed portion of a second metal layer 720, followed by forming the IGZO through etching the exposed portion.

FIG. 7C shows a cross-sectional view of the process architecture including back channel forming for the oxide TFT of the AMLCD following the operation of FIG. 7B. By removing the thinner portion of the photoresist 738A to form photoresist 738B as shown in FIG. 7B, the middle of the first passivation layer 722 and the source/drain 720C can be etched to expose the IGZO, which forms source/drain electrodes 720A-B that are separated by a back channel 736 above the IGZO, as shown in FIG. 7C.

Similar to process architecture 400, architecture 700 uses four additional masks for organic passivation photo patterning, common electrode photo patterning, a second passivation photo patterning, and pixel electrode photo patterning. FIG. 7D shows a cross-sectional view of organic passivation photo patterning and common electrode photo patterning for the oxide TFT of the AMLCD following the operation of FIG. 7C. FIG. 7E shows a cross-sectional view of the process architecture including second passivation photo patterning and pixel electrode photo patterning for the oxide TFT of the AMLCD following the operation of FIG. 7D.

For forming the oxide TFT, the number of masks may be further reduced by using half-tone photoresist. For example, in the case of forming the oxide TFT according to the first embodiment and second embodiments, the number of masks may be reduced from seven to six by using a half-tone photoresist to combine the organic passivation photo and the common electrode photo.

In the case of forming the TFT according to the third embodiment, the number of masks may be reduced from seven to five by using a half-tone photoresist to combine the IGZO photo and the source/drain photo, and another half-tone photoresist to combine the organic passivation photo and the common electrode photo.

In the case of forming the TFT according to the fourth embodiment, the number of masks may be reduced from six to five by using a half-tone photoresist to combine the organic passivation photo and the common electrode photo.

The process architecture of the present disclosure provides several benefits over of the conventional oxide TFT technology. The benefits include reduce the number of mask numbers and increase product throughput at lower production cost.

Having described several embodiments, it will be recognized by those skilled in the art that various modifications, alternative constructions, and equivalents may be used without departing from the spirit of the disclosure. Additionally, a number of well-known processes and elements have not been described in order to avoid unnecessarily obscuring the embodiments disclosed herein. Accordingly, the above description should not be taken as limiting the scope of the document.

Those skilled in the art will appreciate that the presently disclosed embodiments teach by way of example and not by limitation. Therefore, the matter contained in the above description or shown in the accompanying drawings should be interpreted as illustrative and not in a limiting sense. The following claims are intended to cover all generic and specific features described herein, as well as all statements of the scope of the present method and system, which, as a matter of language, might be said to fall therebetween.

What is claimed is:

1. A method of fabricating a back channel etching (BCE) oxide thin film transistor (TFT) for a liquid crystal display, the method comprising:
forming a first metal layer having a first portion and a second portion over a substrate;
depositing a gate insulator over the first metal layer;
disposing a semiconductor layer over the gate insulator;
depositing a half-tone photoresist to cover a first portion of the semiconductor layer and the first portion of the first metal layer, the half-tone photoresist having a first portion and a second portion thicker than the first portion, the first portion having a via hole above the second portion of the first metal layer, the second portion of the half-tone photoresist covering the first portion of the first metal layer;
etching a portion of the gate insulator through the via hole such that the second portion of the first metal layer is exposed;
removing the first portion of the half-tone photoresist while remaining the second portion of the half-tone photoresist; and
etching to remove a second portion of the semiconductor layer that is not covered by the half-tone photoresist.

2. The method of claim 1, further comprising:
depositing a second metal layer over the semiconductor layer and the second portion of the first metal layer;
etching to form a source electrode and a drain electrode over the semiconductor and remain a portion of the second metal layer above the second portion of the first metal layer, the source electrode and the drain electrode being separated by a back channel between the above the semiconductor layer;
depositing a first passivation layer over the source electrode and the drain electrode;
depositing an organic passivation layer over the first passivation layer, the organic insulator layer having a first via hole to expose a portion of the drain electrode and a second via hole to at least partially expose the portion of the second metal layer;
forming a first conductive layer over the organic passivation layer;
depositing a second passivation layer over the first conductive layer; and
forming a second conductive layer over the second passivation layer, the conductive layer having a first portion being connected to the drain electrode through the first via hole and a second portion connecting the second metal layer to the first conductive layer.

3. The method of claim 2, wherein the first passivation layer comprises silicon oxide and the second passivation layer comprises silicon nitride.

4. The method of claim 2, wherein each of the first and second metal layers comprises one or more layers of a conductive material selected from a group consisting of copper, copper alloy, aluminum, aluminum alloy, titanium, and molybdenum. The method of claim 1, wherein the organic insulator layer comprises a photoactive compound (PAC).

5. The method of claim 2, wherein each of the first and second conductive layers comprises indium-tin oxide (ITO).

6. The method of claim 1, wherein the semiconductor layer comprises an oxide semiconductor selected from a group consisting of indium-gallium-zinc-oxide (IGZO), zinc oxide (ZnO), indium oxide (InO), gallium oxide (GaO), tin oxide (SnO2), indium gallium oxide (IGO), indium zinc oxide (IZO), zinc tin oxide (ZTO), and indium zinc tin oxide (IZTO).

7. The method of claim 1, wherein the gate insulator comprises one or more layers of one or more dielectric materials, each material being selected from a group consisting of silicon oxide (SiO₂), silicon nitride (SiNx), aluminum oxide (Al₂O₃), and organic material.

8. The method of claim 1, wherein the substrate comprises a glass.

9. A method of fabricating a back channel etching (BCE) oxide thin film transistor (TFT) for a liquid crystal display, the method comprising:
forming a first metal layer having a first portion and a second portion over a substrate;
depositing a gate insulator over the first metal layer;
disposing a semiconductor layer over the gate insulator;
depositing a second metal layer to form a source electrode and a drain electrode over the semiconductor layer, the source electrode and drain electrode being above the first portion of the first metal layer;
disposing a first passivation layer over the source electrode and drain electrode, the first passivation layer having a first portion over the source electrode and the drain electrode and a second portion beyond the source electrode and the drain electrode;
covering the first portion of the first passivation layer by a photoresist layer;
etching to remove the second portion of the first passivation layer; and
etching to remove a first portion of the semiconductor layer such that a remaining second portion of the semiconductor layer has substantially the same dimension as the first portion of the first passivation layer.

10. The method of claim 9, further comprising:
depositing an organic passivation layer over the first passivation layer,
patterning the organic passivation layer to form a first via hole above the drain electrode and a second via hole above the second portion of the first metal layer;
forming a first conductive layer over the organic passivation layer;
depositing a second passivation layer over the first conductive layer; and
etching the second passivation layer and the first passivation layer through the first via hole to partially expose the drain electrode and etching the gate insulator through the second via hole to partially expose the second portion of the first metal layer;
forming a second conductive layer over the second passivation layer, the second conductive layer having a first portion connected to the drain electrode through the first via hole and a second portion connecting the first conductive layer to the second portion of the first metal layer, the first portion of the second conductive layer being disconnected from the second portion of the second conductive layer.

11. The method of claim 9, wherein the source electrode and the drain electrode are separated by a back channel above the semiconductor.

12. The method of claim 10, wherein the first passivation layer comprises silicon oxide and the second passivation layer comprises silicon nitride. The method of claim 10, wherein each of the first metal layer and the second metal layer comprises one or more layers of a conductive material selected from a group consisting of copper, copper alloy, aluminum, aluminum alloy, titanium, and molybdenum.

13. The method of claim 10, wherein the organic insulator layer comprises a photoactive compound (PAC).

14. The method of claim 10, wherein each of the first conductive layer and the second conductive layer comprises indium-tin oxide (ITO).

15. The method of claim 10, wherein the semiconductor layer comprises an oxide semiconductor selected from a group consisting of indium-gallium-zinc-oxide (IGZO), zinc oxide (ZnO), indium oxide (InO), gallium oxide (GaO), tin oxide (SnO2), indium gallium oxide (IGO), indium zinc oxide (IZO), zinc tin oxide (ZTO), and indium zinc tin oxide (IZTO).

16. The method of claim 10, wherein the gate insulator comprises one or more layers of one or more dielectric materials, each material being selected from a group consisting of silicon oxide (SiO₂), silicon nitride (SiNx), aluminum oxide (Al₂O₃), and organic material.

17. The method of claim 10, wherein the substrate comprises a glass.

18. A method of fabricating a back channel etching (BCE) oxide thin film transistor (TFT) for a liquid crystal display, the method comprising:
forming a first metal layer having a first portion and a second portion over a substrate;
depositing a gate insulator over the first metal layer;
forming a patterned semiconductor layer over the gate insulator above the first portion of the first metal layer;
depositing a second metal layer to form a source electrode and a drain electrode over the patterned semiconductor layer; and
depositing an organic passivation layer over the source electrode and the drain electrode.

19. The method of claim 18, further comprising:
patterning the organic passivation layer to form a first via hole above the drain electrode and a second via hole above the second portion of the first metal layer;
depositing a first conductive layer over the organic passivation layer;
depositing a passivation layer over the first conductive layer; and
etching the passivation layer and the gate insulator through the second via hole to partially expose the second portion of the first metal layer;
forming a second conductive layer over the passivation layer, the second conductive layer having a first portion connected to the drain electrode through the first via hole and a second portion connecting the second portion of the first metal layer to the first conductive layer, the first portion of the second conductive layer being disconnected from the second portion of the second conductive layer.

20. The method of claim 19, wherein the source electrode and the drain electrode are separated by a back channel above the semiconductor.

21. The method of claim 19, wherein the passivation layer comprises a material selected from a group consisting of silicon oxide, silicon nitride, and aluminum oxide.

22. The method of claim 19, wherein each of the first metal layer and the second metal layer comprises one or more layers of a conductive material selected from a group consisting of copper, copper alloy, aluminum, aluminum alloy, titanium, and molybdenum.

23. The method of claim 19, wherein the organic insulator layer comprises a photoactive compound (PAC).

24. The method of claim 19, wherein each of the first conductive layer and the second conductive layer comprises indium-tin oxide (ITO).

25. The method of claim 19, wherein the semiconductor layer comprises an oxide semiconductor selected from a group consisting of indium-gallium-zinc-oxide (IGZO), zinc oxide (ZnO), indium oxide (InO), gallium oxide (GaO), tin oxide (SnO2), indium gallium oxide (IGO), indium zinc oxide (IZO), zinc tin oxide (ZTO), and indium zinc tin oxide (IZTO).

26. The method of claim 19, wherein the gate insulator comprises one or more layers of one or more dielectric materials, each material being selected from a group consisting of silicon oxide (SiO₂), silicon nitride (SiNx), aluminum oxide (Al₂O₃), and organic material.

27. A method of fabricating a back channel etching (BCE) oxide thin film transistor (TFT) for a liquid crystal display, the method comprising:
forming a first metal layer having a first portion and a second portion over a substrate;
forming a plurality of layers over the first metal layer, the plurality of layers comprising a gate insulator over the first metal layer, a semiconductor layer over the gate insulator, a second metal layer over the semiconductor layer, and a first passivation layer over the second metal layer, wherein each of the semiconductor layer, the second metal layer, and the first passivation layer comprises a first portion above the first portion of the first metal layer;
forming a half-tone photoresist over the first portion of the first passivation layer, the half-tone photoresist having a first middle portion being thinner than a second remaining portion;
etching to remove a second portion of the first passivation layer, a second portion of the second metal layer, and a second portion of the semiconductor layer, the second portions being not covered by the half-tone photoresist;
removing the first middle portion of the half-tone photoresist; and
etching to remove a portion of the first passivation layer and a portion of the second metal layer to form a source electrode and a drain electrode separated by a back channel above the semiconductor layer.

28. The method of claim 27, further comprising:
depositing an organic passivation layer over the first passivation layer;
patterning the organic passivation layer to form a first via hole above the drain electrode and a second via hole above the second portion of the first metal layer;
forming a first conductive layer over the organic passivation layer;
depositing a second passivation layer over the first conductive layer; and
etching the second passivation layer and the first passivation layer through the first via hole to partially expose the drain electrode and etching the second passivation layer and the gate insulator through the second via hole to partially expose the second portion of the first metal layer;
forming a second conductive layer over the second passivation layer, the second conductive layer having a first portion connected to the drain electrode through the first via hole and a second portion connecting the second portion of the first metal layer to the first conductive layer through the second via hole, the first portion of the second conductive layer being disconnected from the second portion of the second conductive layer.

29. The method of claim 28, wherein each of the first and second passivation layers comprises a material selected from a group consisting of silicon oxide, silicon nitride, and aluminum oxide.

30. The method of claim 28, wherein each of the first metal layer and the second metal layer comprises one or more layers of a conductive material selected from a group consisting of copper, copper alloy, aluminum, aluminum alloy, titanium, and molybdenum.

31. The method of claim 28, wherein the organic insulator layer comprises a photoactive compound (PAC).

32. The method of claim 28, wherein each of the first conductive layer and the second conductive layer comprises indium-tin oxide (ITO).

33. The method of claim 28, wherein the semiconductor layer comprises an oxide semiconductor selected from a group consisting of indium-gallium-zinc-oxide (IGZO), zinc oxide (ZnO), indium oxide (InO), gallium oxide (GaO), tin oxide (SnO2), indium gallium oxide (IGO), indium zinc oxide (IZO), zinc tin oxide (ZTO), and indium zinc tin oxide (IZTO).

34. The method of claim 28, wherein the gate insulator comprises one or more layers of one or more dielectric materials, each material being selected from a group consisting of silicon oxide (SiO₂), silicon nitride (SiNx), aluminum oxide (Al₂O₃), and organic material.
